(19) United States
(12) Patent Application Publication
(10) Pub. No.: US 2008/0199633 A1
(43) Pub. Date: Aug. 21, 2008

(54) Method of making the luminous tapeline

(75) Inventors: Jung-Hua Weng, Taoyuan County (TW); Yu-Chih Wang, Taoyuan County (TW); Sung-Yi Weng, Taoyuan County (TW); Cheng-Hung Weng, Taoyuan County (TW)

Correspondence Address: WPAT, PC, 7225 BEVERLY ST., ANNANDALE, VA, 22003, US

(73) Assignee: HUAI MAO CORPORATION, Taoyuan County (TW)

(21) Appl. No.: 12/025,098

(22) Filed: Feb. 4, 2008

Related U.S. Application Data
(60) Provisional application No. 60/901,656, filed on Feb. 16, 2007.

(51) Int. Cl. C23C 14/28

(52) U.S. Cl. 427/595

(57) ABSTRACT

The present invention discloses a method of making the luminous tapeline comprising: forming a primer paint layer on a steel material, forming a scale ink layer on the primer paint layer, forming a protection layer on the scale ink layer. The tapeline can be made luminous through one of the following methods, or any combination thereof: transferring and painting a luminous ink on the primer paint layer, spaying a luminous powder on the primer paint layer, and spaying a luminous powder on protection layer.

### BACKGROUND OF THE INVENTION

1. Field of the Invention

The present invention is generally related to the method of making the tapeline, and more particularly, a method of making the luminous tapeline.

2. Description of the Prior Art

Tapeline and long iron tape are the indispensable tools in the daily life nowadays. People use it to measure size, length of things. Based on the different scales and styles on the tapes are usually used in architecture. All sorts of tapes with different shapes, sizes are chose by people in the marketing now. Most of them are used in construction. The scale on the tape is macroscopic in the day time. However there is a problem, people have to build the general large-scale buildings or constructions at night. The light at night is too insufficient for workers. That's inconvenient for workers if they can rarely see clear the scale on the tape at night. Based on this issue, to develop the new style of tapeline or long iron tape is necessary which can solve the insufficient light problem.

### SUMMARY OF THE INVENTION

In accordance with the present invention, a method of making the luminous tapeline is provided.

The present invention discloses a method of making the luminous tapeline comprising: forming a primer paint layer on a steel material, forming a scale ink layer on the primer paint layer, forming a protection layer on the scale ink layer. The tapeline can be made luminous through one of the following methods, or any combination thereof: transferring and painting a luminous ink on the primer paint layer, spaying a luminous powder on the primer paint layer, and spaying a luminous powder on protection layer.

### DESCRIPTION OF THE PREFERRED EMBODIMENTS

What is probed into the invention is a method of making the luminous tapeline. Detail descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details to avoid unnecessary limits of the invention. Some preferred embodiments of the present invention will now be described in greater detail in the following specification. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

The first embodiment of the present invention discloses the method of making the luminous tapeline. The flow chart comprises for four major steps. The first step is forming a primer paint layer on a steel material. The second step is transferring and painting a luminous ink on the primer paint layer to form a scale precursor layer. The above-mentioned luminous ink comprises luminous powder and photo-curable resin. The photo-curable resin comprises one selected from the group consisting of the following: acrylic acid resin, alkyl acrylic acid resin, vinyl resins, epoxide. The third step is photo-curing the scale precursor layer to form a scale ink layer. The thickness of scale ink layer is less than or equal to 20 um, and the best is less than or equal to 10 um. The fourth step is forming a protection layer on the scale ink layer.

The first example of this embodiment is shown that the process of forming a primer paint layer on a steel material comprising: Firstly, a primer paint on a steel material is coated, and then a certain thickness the primer paint layer is scratched to form an intermediate layer on the steel material. The thickness of the intermediate layer is less than or equal to 20 um, and the best is less than or equal to 10 um. Secondly, the luminous powder is spayed evenly on the intermediate layer such that the luminous powder attaches on the intermediate layer. In addition, the diameter of the luminous powder is less than or equal to 10 um, and the best is less than or equal to 5 um. Finally, a first curing-process is performed to cure the intermediate layer and the luminous powder which attaches on the intermediate layer at the same time. The above-mentioned first curing-process can be the light-curing or thermosetting process.

The second example of this embodiment is shown that the process of forming a protection layer comprising: Firstly, the protection paint is coated on the scale ink layer, and then a certain thickness the protection paint is scratched to form a proactive precursor layer. The thickness of the protective precursor layer is less than or equal to 20 um, and the best is less than or equal to 10 um. Secondly, the luminous powder is sprayed evenly on the proactive precursor layer such that the luminous powder attaches on the proactive precursor layer. In addition, the diameter of the luminous powder is less than or equal to 10 um, and the best is less than or equal to 5 um. Finally, a second curing-process is performed to cure the proactive precursor layer and the luminous powder which attaches on the proactive precursor layer at the same time. The above-mentioned second curing-process can be the light-curing or thermosetting process.

The second embodiment of the present invention discloses the method of making the luminous tapeline. The first step is forming a primer paint layer on a steel material. The second step is forming a scale link layer on the primer paint layer. The third step is coating a protection paint on the scale ink layer and then scratching a certain thickness the protection paint to form a proactive precursor layer on the scale ink layer. The fourth step is spaying the luminous powder evenly on the proactive precursor layer such that the luminous powder attaches on the proactive precursor layer. The fifth step is performing a first curing-process to cure the proactive precursor layer and the luminous powder which attaches on the proactive precursor layer at the same time, so as to form a protection layer. The above-mentioned protective precursor layer and the luminous powder attached layer, or the diameter of the luminous powder are all the same as the first embodiment.

The example of this embodiment is shown that the process of forming a primer paint layer on a steel material comprising: Firstly, a primer paint layer is formed on a steel material, and then scratch a certain thickness layer of the primer paint layer to form an intermediate layer. Secondly, the luminous powder is spayed evenly on the intermediate layer such that the luminous powder attaches on the intermediate layer. Finally, a second curing-process is performed to cure the intermediate layer and the luminous powder which attaches on the intermediate layer at the same time, so as to form a primer paint layer. The above-mentioned second curing-process can be the light-curing or thermosetting process. The above-mentioned intermediate layer and the luminous powder attached layer, or the diameter of the luminous powder are all the same as the first embodiment. The above-mentioned luminous powder is the same type used in the process of forming primer paint layer.

The third embodiment of the present invention discloses the method of making the luminous tapeline. The first step is forming a primer paint layer on a steel material and then scratching a certain thickness layer of the primer paint layer to form an intermediate layer. The second step is spaying the luminous powder evenly on the intermediate layer such that the luminous powder attaches on the intermediate layer. The third step is performing a curing-process to cure the intermediate layer and the luminous powder which attaches on the intermediate layer at the same time, so as to form a primer paint layer. The fourth step is forming a scale link layer on the primer paint layer. The fifth step is coating a protection paint on the scale ink layer. The above-mentioned curing-process can be the light-curing or thermosetting process. The above-mentioned protect precursor layer and the luminous powder attached layer, or the diameter of the luminous powder are all the same as the first example.

### EXAMPLE 1

This example demonstrates the method of making the luminous tapeline. First, the Carbon Steel is provided. The content of carbon is about 35 C-105 C. According to the AISI Carbon Steel standard, the Carbon Steel be used should be 1030-10955 Carbon Steel. Second, the Carbon Steel is sliced to become the particular thickness Carbon Steel section. Then, the slitting line process is performed to slit the Carbon Steel section to become the certain wideness Carbon Steel strip via the slitting line machine.

The quenched process is performed after the slitting line process, the Carbon Steel strip is warmed up the temperature till 700 degrees Celsius in quenched oven, or the best is the temperature higher than 800 degrees Celsius to 1000 degrees Celsius. Next, the cooling process is performed. Put the quenched Carbon Steel strip in the container to do the fast cooling step, the temperature should reach around 3 degrees Celsius to 20 degrees Celsius, and the Carbon Steel strip will have the particular camber section. Then the cooling Carbon Steel strip should be tempered to be shaped as a Carbon Steel band through tempering process. The temper temperature is around 25 degrees Celsius to 55 degrees Celsius. The purpose of the quenched process is to heat the metal material to some threshold temperature to change the crystal status. Then the fast or slow cooling process will keep the certain crystal status (or some mixture with the special crystal) in the particular temperature. For instance, quench the Carbon Steel strip is to heat the material, then cool it immediately (put it in the cold water) to make the material becomes hard. Although the material will have high hardness after the quenched process, but it also becomes very brittle. “Tempering Process” is the method to increase the toughness of the material. The concept is to heat the quenched material to the temperature under threshold, then cool it down to the room temperature.

The modification process is performed after the tempering process to modify the surface of the Carbon Steel band with chemical solvent. The Carbon Steel band surface will be easier to be coating with paint. The chemical solvent is the pretreatment surface chemicals.

The coating process is performed after the tempering process to coat the primer paint on the Carbon Steel band continually by the scratch painting machine or the roll painting machine and also scratch a certain thickness the primer paint at the same time. Next, the luminous powder is sprayed on the primer paint continually and evenly with spray machine, so as to form a primer paint layer with the night shining character. Then, the ink-painting machine transfers the luminous ink to the primer paint layer. UV light is used to cure the luminous ink. The last step is coating a protection layer to maintain the scale without damage in the cutting and rebuild process. This is a method of making the luminous tapeline.

### EXAMPLE 2

This example demonstrates the method of making the luminous tapeline. The method to make the Carbon Steel band is the same as the example 1.

The coating process is performed after the tempering process to paint the primer paint on the Carbon Steel band continually by the scratch painting machine or the roll painting machine and also scratch a certain thickness layer of the primer paint at the same time, so as to form a primer paint layer. Then, the ink-painting machine will transfer the luminous ink to the primer paint layer. UV light will be used to cure the painting. The last step is applying a protection layer to maintain the scale without damage in the cutting and rebuild process. This is a method of making the luminous tapeline.

### EXAMPLE 3

This example demonstrates the method of making the luminous tapeline. The method to make the Carbon Steel band is the same as the example 1.

The coating process is performed after the tempering process to paint the primer paint on the Carbon Steel band continually by the scratch painting machine or the roll painting machine and also scratch a certain thickness layer of the primer paint at the same time, so as to form a primer paint layer. Then, the ink-painting machine will transfer the luminous ink to the primer paint layer. UV light will be used to cure the luminous ink and to form a scale ink layer. The last step is painting the protection paint on the scale ink layer continually by the scratch painting machine or the roll painting machine, and then scratching a certain thickness layer of the protection paint at the same time, so as to form a protection layer. Next, the luminous powder is sprayed on the protection layer continually and evenly with spray machine, so as to form a protection layer with the night shining character. The tapeline coating with the luminescent paint will be finished after the cutting and rebuild process.

This invention is used the absorbance light character of the luminous powder or the luminous ink to make luminous tapeline keep blazer at night. The luminous period depends on the absorbance time or the light resource. [1] Use the paint with the luminous powder to make the primer paint on the Carbon Steel, as the example 1. [2] Choose the luminous ink to make the scale on the Carbon Steel, as the example 2. [3] Coating with the luminous powder on the surface to protect the scale, as the example 3. [4] Use all 3 methods as described above, but that cost more.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A method of making the luminous tapeline, comprising:
forming a primer paint layer on a steel material;
transferring and painting a luminous ink on said primer paint layer to form a scale precursor layer, wherein said luminous ink comprises luminous powder and photo-curable resin;
photo-curing said scale precursor layer to form a scale ink layer; and
forming a protection layer on said scale ink layer.

2. The method of making the luminous tapeline according to claim 1, wherein forming a primer paint layer on a steel material comprises:
coating a primer paint on a steel material and then scratching a certain thickness said primer paint to form an intermediate layer on said steel material;
spaying a luminous powder on said intermediate layer such that said luminous powder attaches on said intermediate layer; and
performing a first curing-process to cure said intermediate layer and said luminous powder.

3. The method of making the luminous tapeline according to claim 2, wherein the thickness of said intermediate layer is less than or equal to 20 um.

4. The method of making the luminous tapeline according to claim 2, wherein the attaching thickness of said luminous powder is less than or equal to 20 um.

5. The method of making the luminous tapeline according to claim 2, wherein the diameter of said luminous powder is less than or equal to 10 um

6. The method of making the luminous tapeline according to claim 2, wherein said first curing-process is light-curing-process.

7. The method of making the luminous tapeline according to claim 2, wherein said first curing-process is thermosetting process.

8. The method of making the luminous tapeline according to claim 1, wherein said thickness of scale ink layer is less than or equal to 20 um.

9. The method of making the luminous tapeline according to claim 1, wherein said photo-curable resin comprises one selected from the group consisting of the following: acrylic acid resin, alkyl acrylic acid resin, vinyl resins, epoxide.

10. The method of making the luminous tapeline according to claim 1, wherein forming a protection layer on said scale ink layer comprises:
coating a protection paint on said scale ink layer and then scratching a certain thickness said protection paint to form an proactive precursor layer on said scale ink layer;
spaying a luminous powder on said proactive precursor layer such that said luminous powder attaches on said proactive precursor layer; and
performing a second curing-process to cure said proactive precursor layer and said luminous powder.

11. The method of making the luminous tapeline according to claim 10, wherein the thickness of said protective precursor layer is less than or equal to 20 um.

12. The method of making the luminous tapeline according to claim 10, wherein the attaching thickness of said luminous powder is less than or equal to 20 um.

13. The method of making the luminous tapeline according to claim 10, wherein the diameter of said luminous powder is less than or equal to 10 um

14. The method of making the luminous tapeline according to claim 10, wherein said second curing-process is light-curing-process.

15. The method of making the luminous tapeline according to claim 10, wherein said second curing-process is thermosetting process.

16. A method of making the luminous tapeline, comprising:
forming a primer paint layer on a steel material;
forming a scale ink layer on said primer paint layer;
coating a protection paint on said scale ink layer and then scratching a certain thickness said protection paint to form a proactive precursor layer on said scale ink layer;
spaying a luminous powder evenly on said proactive precursor layer such that said luminous powder attaches on said proactive precursor layer; and
performing a first curing-process to cure said proactive precursor layer and said luminous powder, so as to form a protection layer.

17. The method of making the luminous tapeline according to claim 16, wherein forming a primer paint layer on a steel material comprises:
coating a primer paint on a steel material and then scratching a certain thickness said primer paint to form an intermediate layer on said steel material;
spaying a luminous powder on said intermediate layer such that said luminous powder attaches on said intermediate layer; and
performing a second curing-process to cure said intermediate layer and said luminous powder.

18. A method of making the luminous tapeline, comprising:
coating a primer paint on a steel material and then scratching a certain thickness said primer paint to form an intermediate layer on said steel material;
spaying a luminous powder on said intermediate layer such that said luminous powder attaches on said intermediate layer;
performing a first curing-process to cure said intermediate layer and said luminous powder;
forming a scale ink layer on said primer paint layer; and
forming a protection layer on said scale ink layer.
